(19) United States
(12) Patent Application Publication
(10) Pub. No.: US 2024/0213127 A1
(43) Pub. Date: Jun. 27, 2024

(54) EMBEDDED DIE PACKAGING FOR POWER SEMICONDUCTOR DEVICES FOR IMPROVED SOLDER RELIABILITY

(71) Applicant: GAN SYSTEMS INC., OTTAWA (CA)

(72) Inventors: Abhinandan DIXIT, Kanata (CA); An-Sheng CHENG, Hsinchu City (TW); Di CHEN, Kanata (CA); Hossein MOUSAVIAN, Kanata (CA)

(21) Appl. No.: 18/522,911

(22) Filed: Nov. 29, 2023

Related U.S. Application Data
(60) Provisional application No. 63/434,152, filed on Dec. 21, 2022.

(51) Int. Cl. H01L 23/495; H01L 21/8234; H01L 23/00; H01L 25/065

(52) U.S. Cl. CPC H01L 23/49575; H01L 21/823475; H01L 23/49568; H01L 24/16; H01L 24/97; H01L 25/0657; H01L 2224/16056; H01L 2224/16227; H01L 2224/97; H01L 2225/06517; H01L 2225/06544; H01L 2924/1033; H01L 2924/13064

(57) ABSTRACT

A laminated embedded die package for a power semiconductor device, wherein a laminated body comprises a layup of a plurality of electrically conductive layers and dielectric layers. The die may be mounted in thermal contact with a leadframe. Electrical connections between contact areas of the die, external contact pads of the package and internal conductive layers are made by electrically conductive vias or microvias, formed by laser drilling of vias through the dielectric layers, which are then filled with conductive metal. A plurality of unfilled half-vias are arranged around edges of the laminated body adjacent external contact pads. Half-vias are formed by laser or mechanical drilling along scribe lines before singulation of packages. Surface plating of the half-vias comprises a solder wettable material. The half-vias are unfilled to form a wettable flank which allows for lateral wicking of solder during surface mounting, to facilitate optical inspection of solder reliability.

### CROSS-REFERENCE TO RELATED APPLICATION(S)

This application claims the benefit of and priority to U.S. Provisional Patent Application Ser. No. 63/434,152 filed on Dec. 21, 2022, and entitled “EMBEDDED DIE PACKAGING FOR POWER SEMICONDUCTOR DEVICES FOR IMPROVED SOLDER RELIABILITY,” which application is expressly incorporated herein by reference in its entirety.

This application is related to United States provisional patent application No. 63/350,562 filed Jun. 9, 2022, entitled “Dual Side-Cooled Embedded Die Packaging for Power Semiconductor Devices”.

This application is related to U.S. patent application Ser. No. 17/728,220 filed Apr. 25, 2022, entitled “Embedded Die Packaging for Power Semiconductor Devices” which is a continuation of U.S. patent application Ser. no. 16/928,305, filed Jul. 14, 2020, of the same title.

### TECHNICAL FIELD

This invention relates to embedded die packaging for power semiconductor devices.

### BACKGROUND

Embedded die packaging solutions that offer low inductance interconnections, and low thermal impedance, are disclosed, for example, in the above-referenced U.S. patent application Ser. no. 16/928,305, filed Jul. 14, 2020, entitled “Embedded Die Packaging for Power Semiconductor Devices”, references cited therein, and non-patent publications relating to GaNPx® embedded die packaging.

U.S. Ser. No. 16/928,305 discloses embedded die packaging for power semiconductor devices which comprises a laminated structure built up from layers of dielectric materials and conductive metal layers. This type of laminated embedded die packaging provides low parasitic inductance in a compact (i.e. small form factor) package for high voltage, high current transistors, such as GaN e-HEMTs. The embedded die package may comprise a laminated body and a die comprising a power semiconductor device. The die is embedded within the laminated body. The laminated body comprises a stack, or layup, of a plurality of dielectric build-up layers (aka pre-preg layers) and a plurality of electrically conductive layers. One of the electrically conductive layers may comprise a leadframe on which the back-side of the die is mounted. Electrical connections between contact areas on the die, external contact areas of the package and the internal electrically conductive layers are provided by electrically conductive vias or microvias which extend through the dielectric layers (no wirebonding). The vias and microvias may be formed by laser drilling. A thermal pad may be provided on a top-side of the package, the bottom-side of the package, or on both sides of the package.

In another type of embedded die packaging, known as plastic packaging, e.g. PQFN plastic packaging, a die is mounted on a leadframe substrate providing a thermal pad and external contact areas, and electrical connections between contact areas on the die and external contact areas of the leadframe are made by wirebonding. The leadframe and die assembly is then encapsulated in a plastic dielectric material to form the package body, e.g. by overmolding.

For use, embedded die packages are surface mounted on a substrate, such as a printed circuit board (PCB), using surface mount technology (SMT), such as soldering, to provide electrical connections to the substrate.

High quality solder connections, without solder voids, are required for device reliability, particularly for high power semiconductor power switching devices. For plastic packaging, the external contact areas may be structured with wettable flanks extending around edges of the package, so that during soldering, solder can flow out laterally, and the solder reliability can be checked by optical inspection. For laminated embedded die packaging, where contact areas are spaced from edges of the package, X-ray inspection may be required to verify solder reliability, e.g. check for solder voids.

There is a need for improved or alternative laminated embedded die packaging for power semiconductor devices, e.g. to facilitate inspection of solder reliability.

### SUMMARY OF INVENTION

The present invention seeks to provide improved or alternative embedded die packaging for power semiconductor devices, e.g. to provide improved solderability and/or facilitate inspection of solder reliability.

Aspects of the invention provide an embedded die package and a method of fabrication.

One aspect provides an embedded die package [per claim 1] comprising a laminated body and a die comprising a power semiconductor device embedded in the laminated body; the laminated body comprises a layup of a plurality of electrically conductive layers and dielectric layers, wherein the die is mounted in thermal contact with a leadframe;

electrical connections between contact areas of the die, external contact pads of the package and internal conductive layers are made by electrically conductive vias or microvias;
a plurality of unfilled half-vias are arranged around edges of the laminated body adjacent external contact pads, the plurality of unfilled half-vias having a surface plating of a solder wettable material.

Another aspect provides [per claim 2] an embedded die package comprising a laminated body and a die comprising a power semiconductor device, the die being embedded within the laminated body, wherein:

the die comprises a patterned layer of conductive metallization on a front-side of the die providing electrical contact areas of the power semiconductor device, and a thermal contact area on a back-side of the die; and
a layer stack of the laminated body comprises:
a first conductive layer comprising a leadframe supporting the die and providing electrical contact areas and a thermal pad, the thermal contact area of the die being in thermal contact with the thermal pad of the leadframe;
a layer stack comprising at least one dielectric layer that embeds the die and at least a first conductive layer patterned to define interconnect areas;
the interconnect areas of the at least first conductive layer being connected by electrically conductive vias to respective electrical contact areas of the power semiconductor device and electrical contact areas of the leadframe; and
a plurality of unfilled half-vias are arranged around edges of the laminated body adjacent external contact pads, the plurality of unfilled half-vias having a surface plating of a solder wettable material.

In example embodiments, the plating of solder wettable material is e.g. ENIG. The unfilled vias may be partially filled with a conductive metal layer underlying the surface plating of the solder wettable material. The unfilled half-vias may have a circular, square or rectangular cross-section, or other shape. The lateral dimensions and vertical dimensions (drilling depth) of the vias is large enough that the vias remain partly unfilled after plating.

For example, in some embodiments the vias extend through a thickness comprising a top package RDL layer and a top dielectric layer, to an underlying package RDL layer, and wherein an unfilled depth of the vias is ≥90 μm. In some embodiments, the vias extend to through a thickness comprising a top package RDL layer, any underlying dielectric layers and underlying package RDL layers to a surface of the leadframe.

In some embodiments, the embedded die package may comprise a layer stack configured for any one of bottom-side cooling, top-side cooling and dual-side cooling, with or without a leadframe. For a leadframe embedded die package, the layer stack may comprise the leadframe and what may be referred to as a 2+0 stack or a 2+1 stack of conductive layers, formed by package RDL. In other embodiments, the leadframe may be omitted and replaced with a metal layer comprising another package RDL layer.

The embedded die package may be surface mounted on a substrate using a solder joint, wherein solder extends from the solder joint into at least part of the plated half-vias arranged around edges of the laminated body The unfilled plated half-vias emulate wettable flanks to allow lateral flow of solder, e.g. to allow automated optical inspection of solder integrity.

Another aspect provides a method [per claim 12] of fabricating the embedded die package, comprising drilling vias along scribe lines between adjacent packages, surface plating the vias while leaving the vias unfilled, singulating the packages by cutting along said scribe lines to form said plurality of unfilled plated half-vias along edges of the embedded die package.

Also provided is a method of surface mounting an embedded die package of an example embodiment comprises after surface mounting by soldering, performing an automated optical inspection of solder fillets in plated half-vias to verify solder reliability.

Embedded die packages of example embodiments are described which provide for improved solderability, and facilitate optical inspection of solder reliability of surface mounted packages.

### BRIEF DESCRIPTION OF THE DRAWINGS

FIG. 1A shows a 3D rendering of a PQFN plastic package;

FIG. 1B shows an enlarged view of part of the 3D rendering of the PQFN plastic package of FIG. 1A;

FIG. 2 shows a schematic diagram to surface mounting of a PQFN plastic package after soldering to a contact areas of a PCB substrate;

FIG. 3 shows a schematic cross-sectional diagram to illustrate part of a PQFN plastic package having a wettable flank, after soldering to a contact area of a PCB substrate;

FIG. 4A shows 3D renderings of a dual-side cooled embedded die package of example embodiments;

FIGS. 4B and 4C show schematic diagrams of the bottom-side and top-side of embedded die packages of example embodiments;

FIG. 5 shows a schematic top plan view of a semiconductor die comprising an E-mode lateral GaN HEMT of an example embodiment to illustrate a device topology with large area source and drain contact areas and dual gate contact areas;

FIG. 6 shows a schematic plan view of the bottom side of a dual-side cooled embedded die package of an example embodiment;

FIG. 7 shows a schematic cross-sectional view through plane A-A of FIG. 5 to illustrate the laminated multilayer structure of a dual-side cooled embedded die package surface mounted on a PCB substrate;

FIG. 8 shows a schematic cross-sectional view of the laminated multilayer structure of a dual-side cooled embedded die package surface of a first example embodiment comprising unfilled half-vias;

FIG. 9 shows a schematic plan view of the bottom side of the dual-side cooled embedded die package of the first example embodiment comprising unfilled half-vias;

FIG. 10 shows a schematic plan view of the bottom side of a plurality of dual-side cooled embedded die package of the first example embodiment comprising unfilled half-vias;

FIG. 11A shows a schematic plan view of part of a device structure of an example embodiment with drilled vias on a scribe line between two packages;

FIG. 11B shows a schematic plan view of part of a device structure of an example embodiment with drilled vias on a scribe line between two packages, after formation of pad metal;

FIG. 11C shows a schematic plan view of part of a device structure comprising a package of an example embodiment comprising plated edge half-vias, after singulation;

FIG. 12 shows a schematic cross-sectional view of the laminated multilayer structure of a dual-side cooled embedded die package surface of the first example embodiment mounted on a PCB substrate;

FIG. 13 shows a schematic cross-sectional view of the laminated multilayer structure of a dual-side cooled embedded die package surface of a second example embodiment;

FIG. 14 shows a schematic cross-sectional view of the laminated multilayer structure of a dual-side cooled embedded die package surface of a second example embodiment with unfilled plate half-vias;

FIG. 15 shows a flowchart representing steps in a first process flow for fabrication of embedded die packages of example embodiments comprising unfilled plated half-vias;

FIG. 16 shows a schematic cross-sectional view of the laminated multilayer structure of a dual-side cooled embedded die package surface of a third example embodiment with unfilled plated half-vias;

FIG. 17A, 17B, 17C, 17D, 17E, 17F and 17G show schematic cross-sectional views of part of a device structure to represent steps in a process for forming embedded die packages of example embodiment comprising unfilled plated half-vias;

FIGS. 18A, 18B, 18C and 18D show schematic plan views of part of a device structure to represent steps in a process for forming embedded die packages of example embodiments comprising unfilled plated half-vias;

FIG. 19 shows a cross-sectional electron micrograph of a half-via of an embodiment; and

FIG. 20 shows a flowchart representing steps in a second process flow for fabrication of embedded die packages of example embodiments comprising unfilled plated half-vias.

The foregoing and other features, aspects and advantages will be more apparent from the following detailed description, taken in conjunction with the accompanying drawings, of example embodiments, which description is by way of example only.

### DETAILED DESCRIPTION

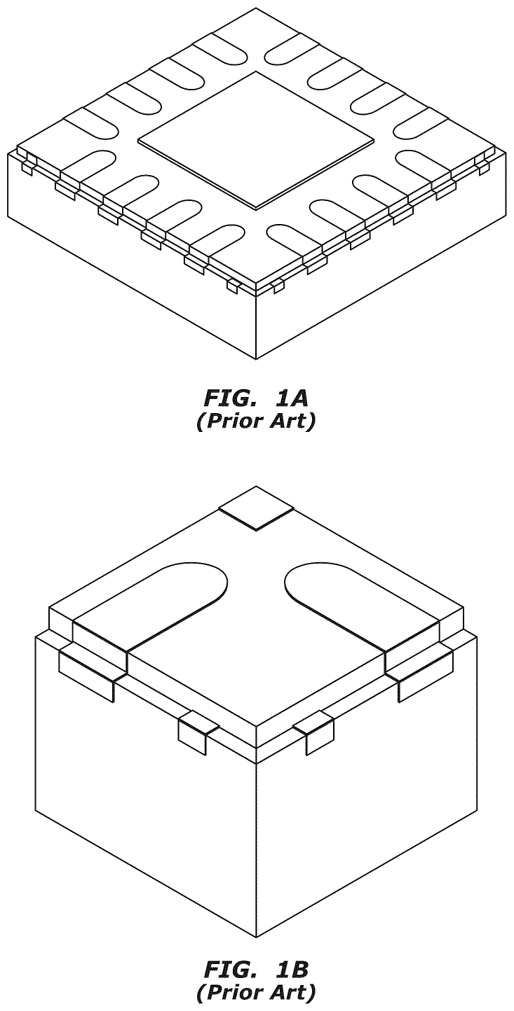

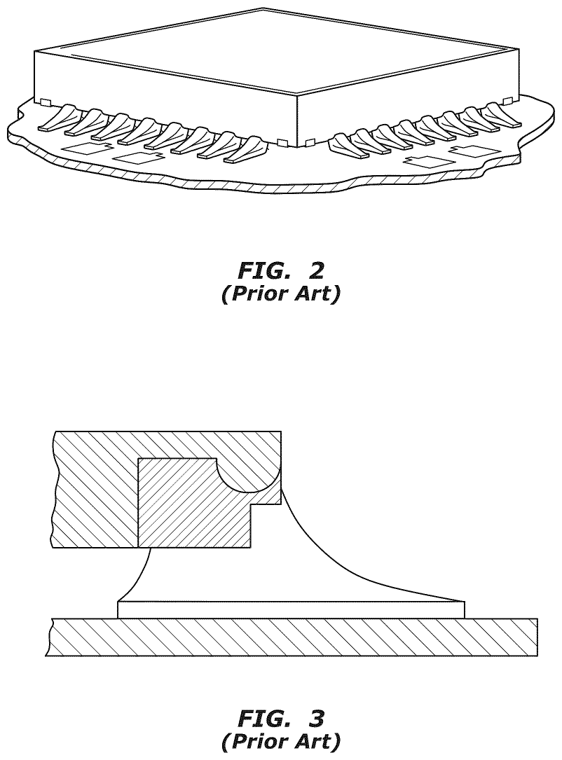

FIG. 1A shows a 3D rendering of a PQFN plastic package, comprising a thermal pad, a plurality of package leads and a dielectric body comprising a plastic material embedding or encapsulating a power semiconductor die. FIG. 1B shows an enlarged 3D rendering of part of the PQFN plastic package of FIG. 1A to illustrate a wettable flank to facilitate surface mounting of the package by soldering. The wettable flank may be formed by cutting a step around the edge of the package body and plating the exposed surfaces to provide a solderable edge surface. FIG. 2 shows a 3D view to illustrate surface mounting of a PQFN plastic package on a PCB substrate. FIG. 3 shows a schematic diagram to illustrate part of a PQFN plastic package after soldering of a package lead to a contact of a PCB substrate.

Wettable flanks (WF) are modifications to the exposed terminal ends of the leads, which promote solder wetting for the formation of a solder fillet that is visible around edges of the package. The wettable flanks allow for solder to flow laterally to allow for optical inspection of solder reliability.

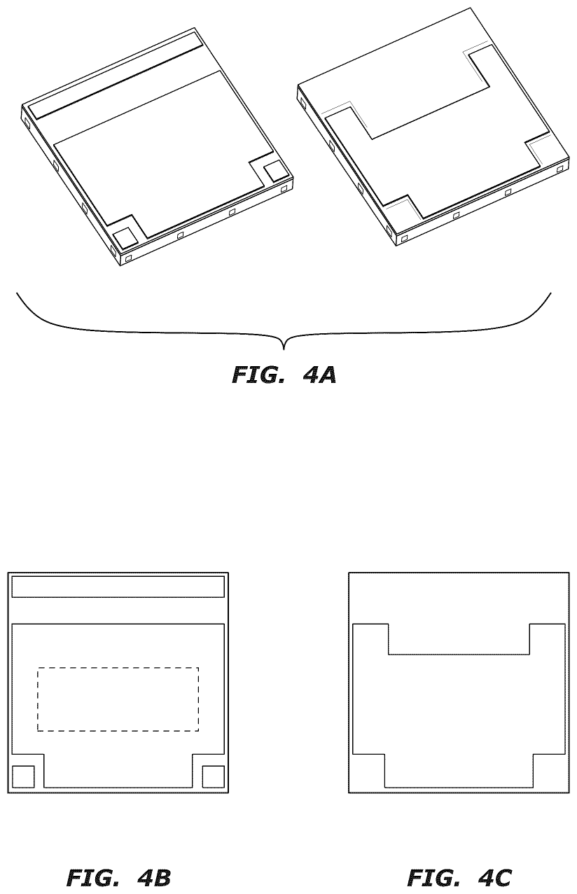

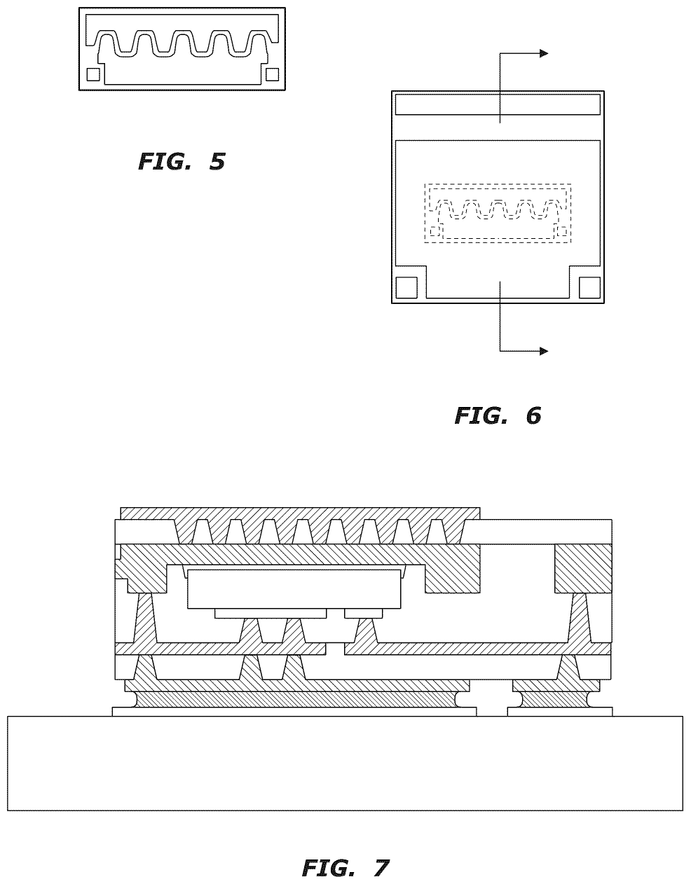

FIG. 4A show 3D renderings of a dual-side cooled embedded die package of another type comprising a laminated dielectric body. FIGS. 4B and 4C show schematic diagrams of the bottom-side and top-side of embedded die packages of example embodiments to illustrate an example arrangement of external contact pads and thermal pad. FIG. 5 shows a schematic top plan view of a power semiconductor die 10 comprising an E-mode lateral GaN HEMT of an example embodiment to illustrate a device topology with large area source and drain contact areas and dual gate contact areas. The die contact areas may be formed from a die metal redistribution layer (RDL), such as a copper (Cu) RDL. FIG. 6 a schematic plan view of the bottom side of a dual-side cooled embedded die package of a first example embodiment to illustrate a power semiconductor die embedded within the package.

FIG. 7 shows a schematic cross-sectional view through plane A-A of FIG. 6 to illustrate the laminated multilayer structure of an example dual-side cooled embedded die package, which is surface mounted on a PCB substrate. In this embodiment, a semiconductor die comprising a power switching device is mounted on a leadframe with die attach material. The die and leadframe are embedded in a laminated package body comprising a plurality of conductive metal layers and dielectric layers. Electrical and thermal connections between the conductive metal layers are made with metal filled vias and microvias.For example, the dielectric layers may be prepreg (PP) layers, comprising glass fiber impregnated with an epoxy resin composite. The leadframe provides one of the conductive layers (Metal 1) The other metal layers (metal 2, 3, 4) are formed from copper foil, which is copper plated to provide a required thickness of conductive metal. Details of the lamination process for fabrication of this embedded die package are provided in the above referenced related patent application.

As illustrated schematically in FIG. 7, since the contact pads are spaced from edges of the package, it is difficult to perform optical inspection for solder reliability, and X-ray inspection may be required to check for solder voids.

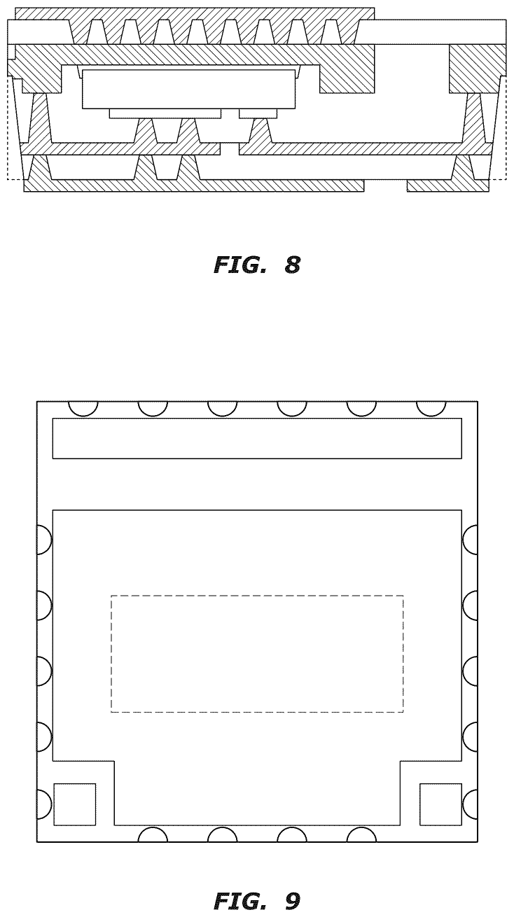

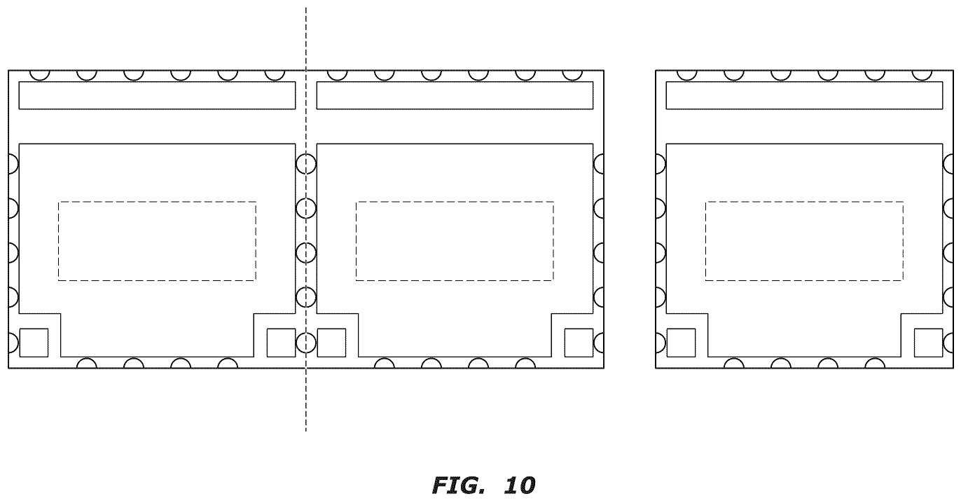

FIG. 8 shows a schematic cross-sectional view of the laminated multilayer structure of a dual-side cooled embedded die package surface of a first example embodiment comprising unfilled half-vias around edges of the package. The unfilled half-vias are plated with a solder wettable material, e.g. electroplated nickel gold (ENIG). As illustrated schematically, the half-vias are drilled through the dielectric material to the edge of the leadframe, e.g. using the leadframe as a drill stop. FIG. 9 shows a schematic plan view of the bottom side of the dual-side cooled embedded die package of the first example embodiment comprising unfilled half-vias along each edge of the package body.

Laminated embedded die packages of this type are fabricated in sheet or strip form with arrays of multiple packages which are singulated by cutting along scribe lines after processing, as illustrated schematically in FIG. 10. To form the unfilled half-vias, large vias are drilled along edges of each package in the scribe channel between each adjacent package. When the packages are separated by cutting along the scribe line (cut line) half-vias remain along the cut edge. The edge vias may be formed by laser drilling or mechanical drilling.

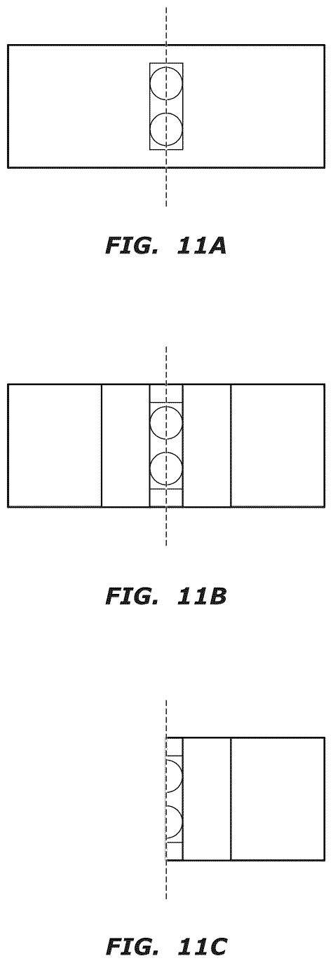

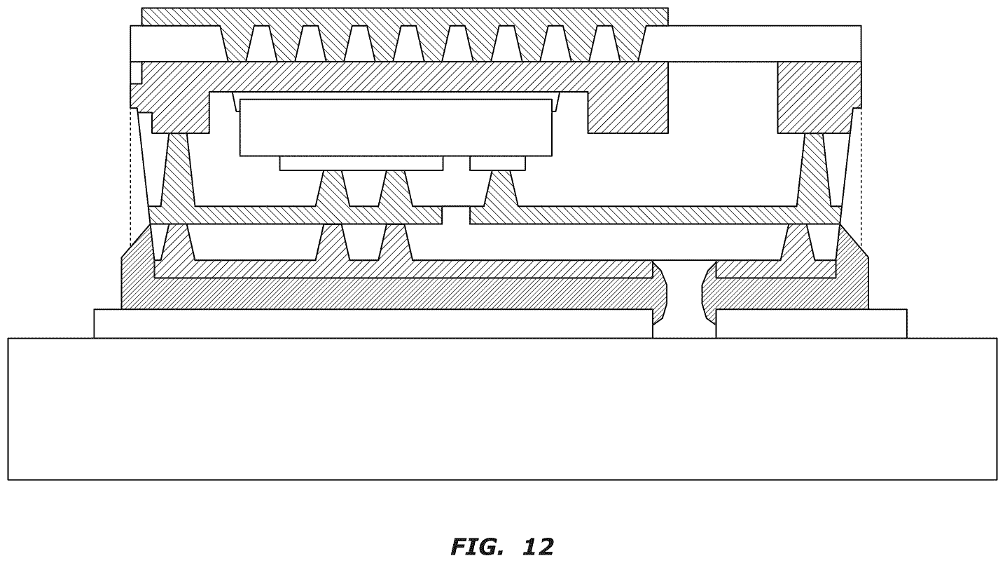

FIG. 11A shows a schematic plan view of part of a device structure of an example embodiment after laser drilling of vias along a scribe line between two adjacent packages. FIG. 11B shows a schematic plan view of part of a device structure of an example embodiment after formation of a contact pad or thermal pad, e.g. by copper plating. In this example process the vias are masked during copper plating, so that the vias are left unfilled. After patterning of the pad metal, the edge vias are unmasked. The copper pads are plated with a solder wettable material, such as ENIG. Since the edge vias are unmasked at this stage, the surfaces of the edge vias are also ENIG plated. FIG. 11C shows a schematic plan view of part of a device structure comprising a package of an example embodiment comprising plated edge half-vias, after singulation.

FIG. 12 shows a schematic cross-sectional view of the embedded die package of FIG. 8, surface mounted on a PCB substrate. As illustrated schematically in FIG. 12, during surface mounting by soldering, the solder wettable coating in the edge half vias enables the solder to flow laterally and wick into at least part of the half-via, to form a solder fillet (solder toe) that is visible at the side of the embedded die package. After surface mounting of embedded die packages of example embodiments using a soldering, it is possible to perform an automated optical inspection of solder fillets in plated half-vias to verify solder integrity and reliability.

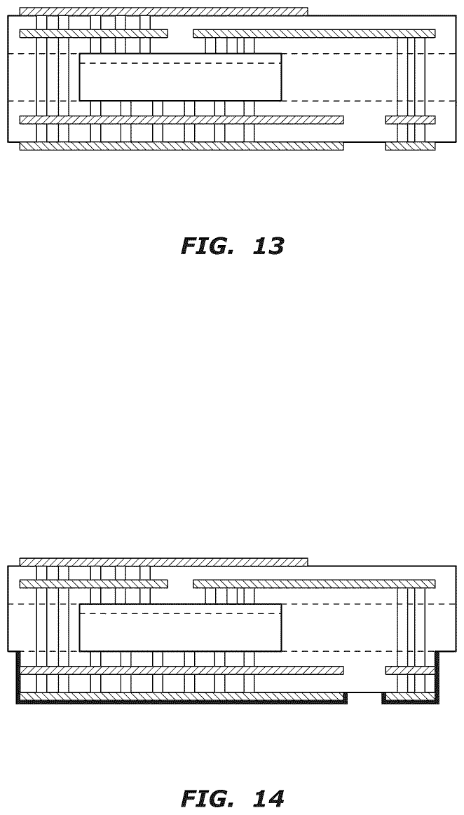

FIG. 13 shows a dual-side cooled embedded die package of another example embodiment comprising a plurality of dielectric layers and conductive layers, in which electrical and thermal connections are made with metal filled vias and microvias extending through the dielectric layers. This example is a layup without a leadframe, in which the die sandwiched between a layer stack comprising two conductive layers on each side of the die. FIG. 14 shows a dual-side cooled embedded die package of FIG. 13 comprising plated edge half-vias. This structure is formed, e.g. by laser drilling of vias into the dielectric material to a required depth along the scribe line between adjacent packages, before singulation. After patterning of the pad metal to form the source pad/thermal pad and drain pad, the vias are plated with solder wettable material at the same time as plating of the pad metal with solder wettable material.

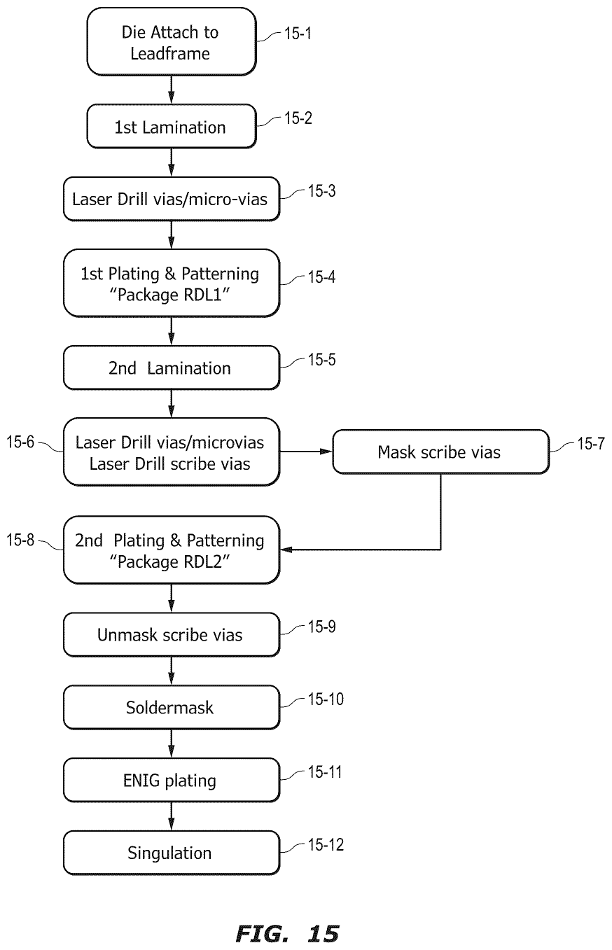

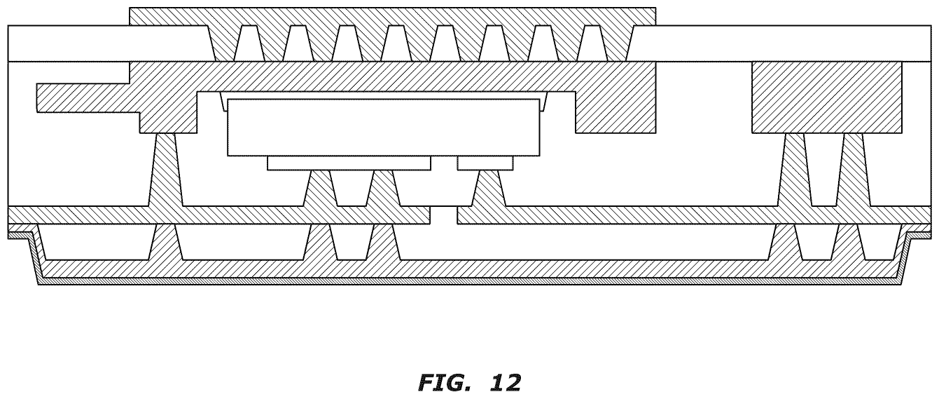

FIG. 15 shows a flowchart representing steps in a first process flow for fabrication of embedded die packages of example embodiments comprising a leadframe, an unfilled plated edge half-vias, e.g. as shown in FIG. 8. In step 15-1, leadframes are provide in strip or sheet form, and the die are attached to each leadframe with die attach material. A first lamination 15-2 is performed to embed the die an at least the top and sides of the leadframe, using a first prepreg layer comprising a dielectric layer and a copper foil layer. Vias and microvias are formed by laser drilling 15-3 to open vias through the dielectric layers for electrical connections to the die and leadframe. In a first plating and patterning process 15-4, the vias and microvias are filled with conductive metal, and a required thickness of copper is provided by copper plating to form a first package RDL. The first package RDL is then patterned to define contact areas for electrical connections and thermal connections. A second lamination 15-5 is performed in which a prepreg layer comprising dielectric layer and copper foil is applied on each side to provide the third and fourth metal layers. After the second lamination, vias and microvias are formed by laser drilling 15-6 to open vias through the dielectric layers for electrical connections to the die and leadframe. Laser drilling is also used to drill scribe vias along the scribe channel around each package body. The scribe vias are then masked 15-7. A second plating and patterning process 15-8 is then performed fill the vias and microvias, and to form the second package RDL. The second package RDL is then patterned to define the external contact pads and thermal pads of the embedded die package. Since the scribe vias are masked, they remain unfilled at this stage. The scribe vias are then unmasked 15-9, prior to plating of the external contact pads and thermal pads with a solder wettable coating, so that the walls of scribe vias become coated with the solder wettable coating. For example, after applying a solder mask coating 15-10, the metal pads and the scribe vias are plated with ENIG 15-11. This leaves unfilled, ENIG plated scribe vias. After singulation of the packages 15-12, unfilled, ENIG plated half-vias remain around edges of each package, e.g. as illustrated schematically in FIGS. 8, 9 and 10.

FIG. 16 shows a schematic cross-sectional view of the laminated multilayer structure of a dual-side cooled embedded die package surface of a third example embodiment with unfilled plated half-vias. In this embodiment, the second metal layer, Metal 2, extends to the scribe line an acts as a drill stop layer during drilling of the scribe vias. The scribe vias are sized to be large enough that during metal plating to fill the vias for electrical and thermal connections and provide the package RDL for the contact pads and thermal pads, the scribe vias are only partially filled by the copper plating.

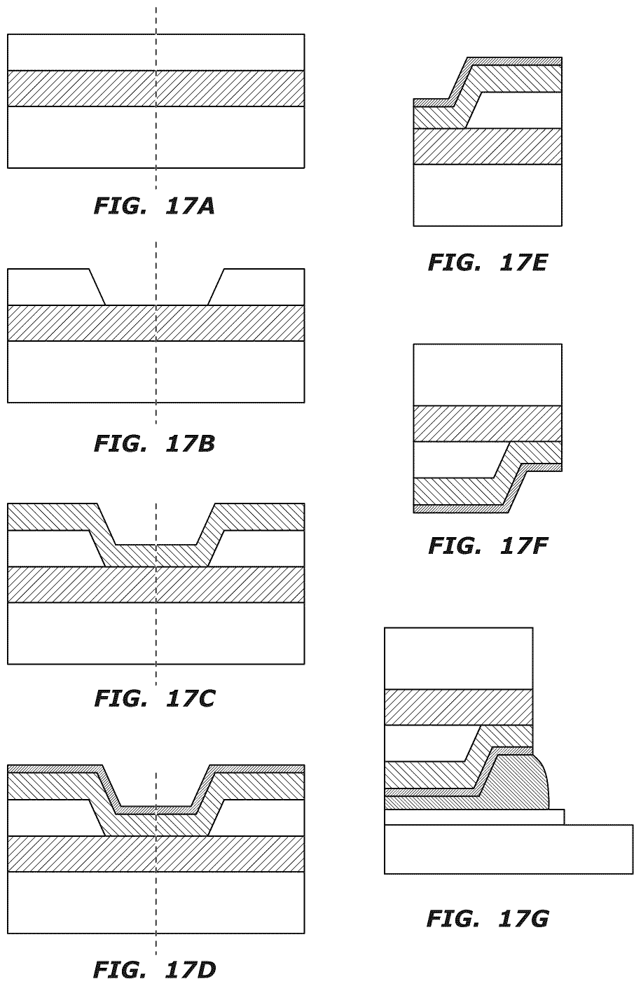

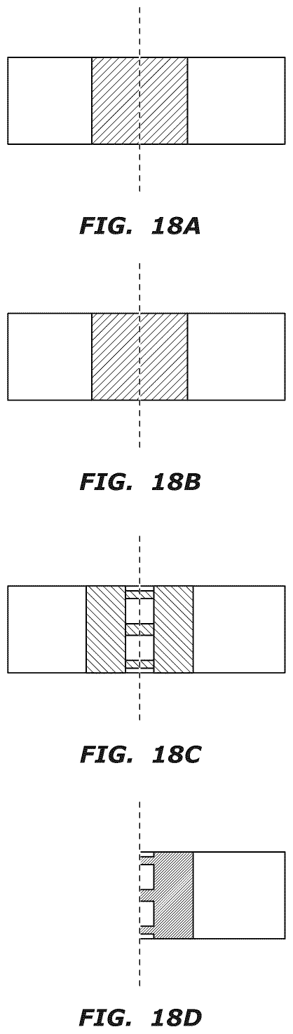

FIG. 17A, 17B, 17C, 17D, 17E, 17F and 17G show schematic cross-sectional views of part of a device structure to represent steps in a process for forming embedded die packages of example embodiments comprising unfilled plated half-vias, and FIGS. 18A, 18B, 18C and 18D show schematic plan views of part of a device structure to represent steps in a process for forming embedded die packages of example embodiments comprising unfilled plated half-vias, e.g. plated half-vias as illustrated schematically in FIG. 16. After providing layers comprising Dielectric 1, Metal 2 and Dielectric 2, as shown schematically in FIG. 17A, vias are drilled along the scribe line as shown schematically in FIG. 17B. As shown schematically in FIGS. 18A and 18B, Metal 2 extends across the scribe channel to act as a drill stop. After plating of Metal 4, the scribe vias are partially filled, as illustrated schematically in FIG. 17C and FIG. 18C. The unfilled scribe vias are then plated with a solder wettable coating, as illustrated schematically in FIG. 17D. After singulation by cutting along the scribe line, plated unfilled edge vias remain around edges of the package body, as shown schematically in FIG. 17E and FIG. 18D. FIG. 17F and FIG. 17G shows a schematic diagram of the structure of FIG. 17E, before and after surface mounting with solder on a pad of a PCB substrate. FIG. 17G, shows schematically where the solder has flowed and wicked into the ENIG plated half-via to form a solder fillet, which can be inspected by optical inspection.

Large scribe vias may be provided by laser drilling or mechanical drilling. The vias may have a circular, square or rectangular cross section. In the structure shown schematically in FIG. 16, the depth of the scribe half-vias can be controlled by the thickness of the second dielectric layer, Dielectric 2, between metal 2 and metal 4. For example, for a metal 4 thickness of e.g. 35 μm, the thickness of dielectric 2 may be made thicker, e.g. ˜100 μm, to provide a plated unfilled half-via having an unfilled depth of at least 90 μm to form a wettable flank of sufficient size for optical inspection of solder fillets after surface mounting of the embedded die package.

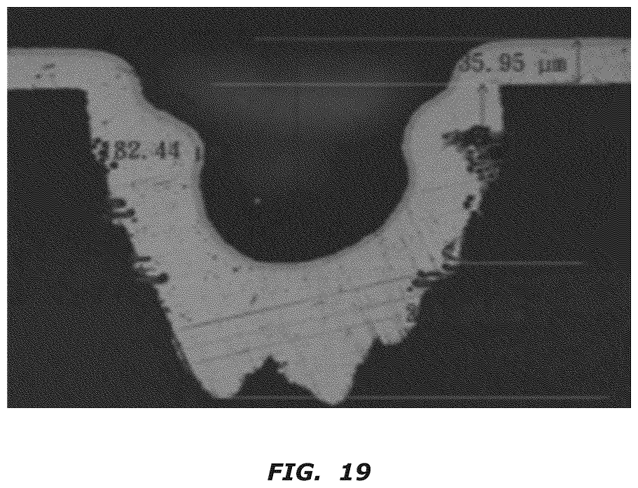

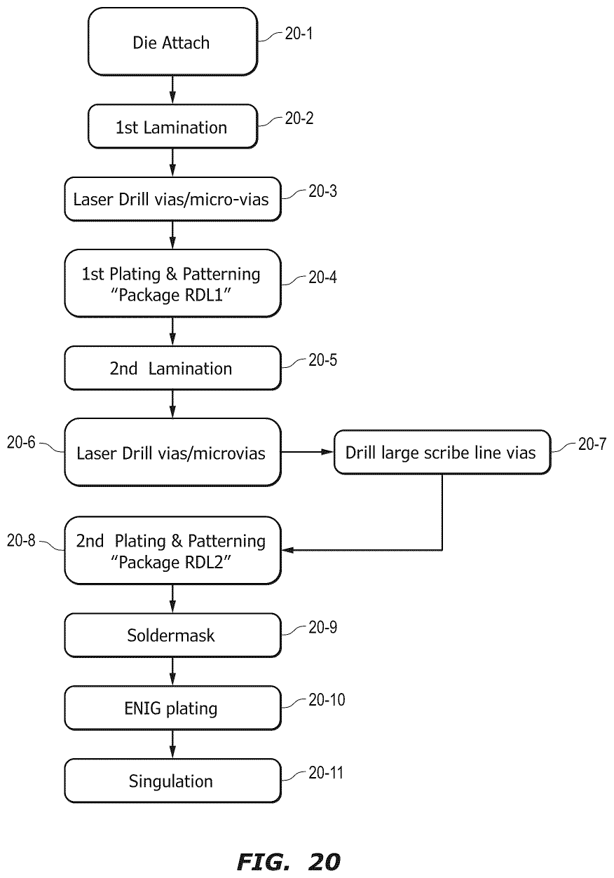

An example electron micrograph of an unfilled edge via is shown in FIG. 19.

FIG. 20 shows a flowchart representing steps in a second process flow for fabrication of embedded die packages of example embodiments comprising unfilled plated half-vias. The second process flow differs from the first process flow shown in FIG. 15, in steps 20-7 and 27-8, because if the scribe vias are large enough, it does not require masking of the scribe vias during the 2^{nd} plating and patterning. As illustrated in the electron micrograph in FIG. 19, large vias are not filled during the second plating for the package RDL2, and the ENIG plating is relatively thin, e.g. typically only a few microns thick.

Process flows of example embodiments do not require modification of the leadframe structure and are based on existing embedded die packaging processes, with minimal additional process steps to form the plated edge half-vias. The edge half-vias can be added with minimal additional cost, using either laser drilling or mechanical drilling, or a combination of drilling processes.

The scribe line unfilled half-vias provided for improved solderability and facilitate solder void inspection using optical inspections. The need for X-ray inspection may be avoided, or reduced, which reduces cost. Solder reliability and avoidance of solder voids is particularly important for applications subject to harsher conditions, such embedded die packaging of power semiconductor switching devices, e.g. GaN HEMTs, for automotive applications, which are required to undergo more rigorous testing and qualification.

The unfilled plated half-vias along edges of the package can be added to laminated embedded die packages in which the layup is configured for top-cooled, bottom-cooled or dual-side cooled configurations. The plated half-vias may be large sized vias to provide solder fillets which are readily visible for automatic optical inspection of solder joint reliability.

Embedded die packages of example embodiments are described which provide for improved solderability, and facilitate optical inspection of solder reliability of surface mounted packages.

Although example embodiments have been described and illustrated in detail, it is to be clearly understood that the same is by way of illustration and example only and not to be taken by way of limitation, the scope of the present invention being limited only by the appended claims.

1. An embedded die package comprising a laminated body and a die comprising a power semiconductor device embedded in the laminated body;
the laminated body comprises a layup of a plurality of electrically conductive layers and dielectric layers, wherein the die is mounted in thermal contact with a leadframe;
electrical connections between contact areas of the die, external contact pads of the package and internal electrically conductive layers are made by electrically conductive vias or microvias;
a plurality of unfilled half-vias are arranged around edges of the laminated body adjacent external contact pads, the plurality of unfilled half-vias having a surface plating of a solder wettable material.

2. An embedded die package comprising a laminated body and a die comprising a power semiconductor device, the die being embedded within the laminated body, wherein:
the die comprises a patterned layer of conductive metallization on a front-side of the die providing electrical contact areas of the power semiconductor device, and a thermal contact area on a back-side of the die; and
a layer stack of the laminated body comprises:
a first conductive layer comprising a leadframe supporting the die and providing electrical contact areas and a thermal pad, the thermal contact area of the die being in thermal contact with the thermal pad of the leadframe;
a layer stack comprising at least one dielectric layer that embeds the die and at least a first conductive layer patterned to define interconnect areas;
the interconnect areas of the at least first conductive layer being connected by electrically conductive vias to respective electrical contact areas of the power semiconductor device and electrical contact areas of the leadframe; and
a plurality of unfilled half-vias are arranged around edges of the laminated body adjacent external contact pads, the plurality of unfilled half-vias having a surface plating of a solder wettable material.

3. The embedded die package of claim 1, wherein the unfilled half-vias comprise a conductive metal layer underlying the surface plating of the solder wettable material.

4. The embedded die package of claim 1, wherein the unfilled half-vias have a circular, square or rectangular cross-section.

5. The embedded die package of claim 1, wherein the lateral dimensions and vertical dimensions (drilling depth) of the vias is large enough that the vias remain partly unfilled.

6. The embedded die package of claim 1, wherein the vias extend through a thickness comprising a top package RDL layer and a top dielectric layer, to an underlying package RDL layer, and wherein an unfilled depth of the vias is ≥90 μm.

7. The embedded die package of claim 1, wherein the vias extend to through a thickness comprising a top package RDL layer, any underlying dielectric layers and underlying package RDL layers to a surface of the leadframe.

8. The embedded die package of claim 1, comprising a layer stack configured for any one of bottom-side cooling, top-side cooling and dual-side cooling.

9. The embedded die package of claim 1, comprising a layer stack configured comprising the leadframe and a 2+0 or 2+1 stack of conductive layers (package RDL).

10. The embedded die package of claim 1, wherein the leadframe is omitted and replaced with a metal layer comprising another package RDL layer.

11. The embedded die package of claim 1, surface mounted on a substrate using a solder joint, wherein a fillet of solder extends from the solder joint into at least part of the plated half-vias arranged around edges of the laminated body.

12. A method of fabricating the embedded die package of claim 1, comprising drilling vias along scribe lines between adjacent packages, surface plating the vias with solder wettable material while leaving the vias unfilled, singulating the packages by cutting along said scribe lines to form said plurality of plated unfilled plated half-vias along edges of the embedded die package.

13. The method of claim 12, wherein after drilling the vias along scribe lines, the vias are masked during subsequent plating and patterning of package RDL, and the vias are unmasked during surface plating with solder wettable material.

14. The method of claim 12, wherein after drilling the vias along scribe lines, the vias are left unmasked during plating and patterning of package RDL, so that the vias are surface platted with a conductive layer of the package RDL, and a surface plating of the solder wettable material, leaving the vias partly unfilled.

15. The method of claim 12, wherein the lateral dimensions and vertical dimensions (drilling depth) of the vias is large enough that the vias remain partly unfilled.

16. The method of claim 12, wherein the vias extend through a thickness comprising a top package RDL layer and a top dielectric layer, to an underlying package RDL layer, and wherein an unfilled depth of the vias is ≥90 μm.

17. The method of claim 12, wherein the underlying package RDL layer extends across scribe lines so that the underlying package RDL acts as a drill stop during drilling of vias.

18. The method of claim 12, wherein the leadframe acts as a drill stop during drilling of vias.

19. The method of claim 12, wherein drilling comprises any one of laser drilling, mechanical drilling, and a combination of laser and mechanical drilling.

20. A method of surface mounting the embedded die package of claim 1, comprising after surface mounting by soldering, performing an automated optical inspection of solder fillets in plated half-vias to verify solder reliability.
